(19) United States
(12) Patent Application Publication
(10) Pub. No.: US 2024/0146271 A1
(43) Pub. Date: May 2, 2024

(54) UNBALANCED-TO-BALANCED TRANSFORMATION CIRCUIT AND RADIO-FREQUENCY AMPLIFIER

(71) Applicant: Murata Manufacturing Co., Ltd., Kyoto (JP)

(72) Inventors: Masatoshi HASE, Kyoto (JP); Koudai SUGIYAMA, Kyoto (JP); Masamichi TOKUDA, Kyoto (JP); Seiko NETSU, Kyoto (JP)

(21) Appl. No.: 18/499,666

(22) Filed: Nov. 1, 2023

(30) Foreign Application Priority Data
Nov. 2, 2022 (JP) 2022-176241

(51) Int. Cl. H03F 3/60; H01P 5/10; H01P 5/18; H03F 1/56

(52) U.S. Cl. CPC H03F 3/60; H01P 5/10; H01P 5/18; H03F 1/56; H03F 2200/451

(57) ABSTRACT

A first transmission line transformer receives and outputs an unbalanced signal and performs impedance transformation. A second transmission line transformer performs unbalanced-to-balanced transformation. The first transmission line transformer includes a first main line and a first sub-line. The direction of the first main line is identical to the direction of the first sub-line. An end of the first sub-line is grounded. An end of the first main line is coupled to the unbalanced-signal input/output node. The second transmission line transformer includes a second main line and a second sub-line. The direction of the second main line is identical to a direction of the second sub-line. An end of the second main line and the second sub-line are grounded. An end of the second main line and the second sub-line are coupled to the balanced-signal input/output nodes.

### CROSS REFERENCE TO RELATED APPLICATION

This application claims priority from Japanese Patent Application No. 2022-176241 filed on Nov. 2, 2022. The content of this application is incorporated herein by reference in its entirety.

### BACKGROUND ART

The present disclosure relates to a unbalanced-to-balanced transformation circuit and a radio-frequency amplifier.

A known balun for impedance transformation and unbalanced-to-balanced transformation includes an impedance transformation circuit and a unbalanced-to-balanced transformation circuit (a balun) that are cascade-coupled (Hua-Yen Chung, et. Al. “Design of Step-Down Broadband and Low-Loss Ruthroff-Type Baluns Using IPD Technology,” IEEE TRANSACTIONS ON COMPONENTS, PACKAGING AND MANUFACTURING TECHNOLOGY, VOL. 4, NO. 6, pp. 967-974, 2014 (Non Patent Document 1)). The impedance transformation circuit is designed to transform the impedance of unbalanced signals using a Ruthroff-type transmission line transformer. The unbalanced-to-balanced transformation circuit uses a Ruthroff-type transmission line transformer. Each of the impedance transformation circuit and the unbalanced-to-balanced transformation circuit includes a main line and a sub-line, which are transmission lines coupleable by electromagnetic field coupling.

The main line of the impedance transformation circuit and the main line of the unbalanced-to-balanced transformation circuit are provided in the same wiring layer, formed by a continuous metal pattern. The sub-line of the impedance transformation circuit and the sub-line of the unbalanced-to-balanced transformation circuit are also provided in the same wiring layer, formed by a continuous metal pattern. The main lines and the sub-lines are provided in different wiring layers. The main lines overlap the sub-lines in plan view. When impedance matching is achieved at the input/output side, the impedance (unbalanced impedance) observed from an unbalanced port to a balanced port side is greater than or equal to the impedance (balanced impedance) observed from the balanced port to the unbalanced port side.

### BRIEF SUMMARY

In some cases, there is a demand to increase the balanced impedance to a level that is four times or more the unbalanced impedance. The configuration disclosed in Non Patent Document 1, where the impedance transformation circuit and the unbalanced-to-balanced transformation circuit are cascade-coupled, cannot satisfy this demand. The present disclosure provides a unbalanced-to-balanced transformation circuit capable of increasing the balanced impedance to a level that is four times or more the unbalanced impedance. The present disclosure provides a radio-frequency amplifier including the unbalanced-to-balanced transformation circuit.

According to an aspect of the present disclosure, there is provided a unbalanced-to-balanced transformation circuit including a first transmission line transformer configured to perform impedance transformation, the first transmission line transformer being configured to receive an unbalanced signal as an input signal and output an unbalanced signal as an output signal, a second transmission line transformer configured to perform unbalanced-to-balanced transformation, an unbalanced-signal input/output node, and a pair of balanced-signal input/output nodes. The first transmission line transformer includes a first main line and a first sub-line. The first main line and the first sub-line are coupled such that the direction from a first end, which is one end of the first main line, to a second end, which is the other end of the first main line, is Identical to the direction from a third end, which is one end of the first sub-line, to a fourth end, which is the other end of the first sub-line. The fourth end is coupled to the first end. The third end is grounded. The first end is coupled to the unbalanced-signal input/output node. The second transmission line transformer includes a second main line and a second sub-line. The second main line and the second sub-line are coupled such that the direction from a fifth end, which is one end of the second main line, to a sixth end, which is the other end of the second main line, is identical to the direction from a seventh end, IIch is one end of the second sub-line, to an eighth end, which is the other end of the second sub-line. The fifth end is coupled to the second end. The sixth end and the seventh end are grounded. The fifth end and the eighth end are respectively coupled to the pair of balanced-signal input/output nodes.

According to another aspect of the present disclosure, there is provided a radio-frequency amplifier including a differential amplifier including a pair of input nodes and a pair of output nodes and one or two unbalanced-to-balanced transformation circuits, each being the unbalanced-to-balanced transformation circuit described above. The unbalanced-to-balanced transformation circuits include a first unbalanced-to-balanced transformation circuit, and the pair of balanced-signal input/output nodes of the first unbalanced-to-balanced transformation circuit is coupled to one pair of the pair of input nodes and the pair of output nodes of the differential amplifier.

This configuration ensures that the balanced impedance can be made greater than or equal to the unbalanced impedance.

### BRIEF DESCRIPTION OF THE DRAWINGS

FIG. 1 is an equivalent circuit diagram of a unbalanced-to-balanced transformation circuit according to a first embodiment;

FIG. 2A is a plan view of the unbalanced-to-balanced transformation circuit according to the first embodiment, and FIG. 2B is a sectional view of a portion of the unbalanced-to-balanced transformation circuit according to the first embodiment;

FIG. 3 schematically illustrates the shapes of the transmission lines of the unbalanced-to-balanced transformation circuit according to the first embodiment, as viewed in plan view;

FIGS. 4A, 4B, 4C, and 4D schematically illustrate positional relationships between a first transmission line transformer and a second transmission line transformer of a unbalanced-to-balanced transformation circuit, according to comparative examples, as viewed in plan view;

FIG. 5 schematically illustrates the shapes of the transmission lines of a unbalanced-to-balanced transformation circuit according to a modification of the first embodiment, as viewed in plan view;

FIG. 6 schematically illustrates a positional relationship among transmission lines in a unbalanced-to-balanced transformation circuit according to a second embodiment, as viewed in plan view;

FIG. 7A schematically illustrates a positional relationship among transmission lines in a unbalanced-to-balanced transformation circuit according to a third embodiment, as viewed in plan view, and FIG. 7B is a sectional view of a portion of the unbalanced-to-balanced transformation circuit according to the third embodiment;

FIG. 8 is an equivalent circuit diagram of a unbalanced-to-balanced transformation circuit according to a fourth embodiment;

FIG. 9 is an equivalent circuit diagram of a radio-frequency amplifier according to a fifth embodiment;

FIG. 10 is an equivalent circuit diagram of a first transmission line transformer of a unbalanced-to-balanced transformation circuit according to a sixth embodiment; and

FIG. 11 is an equivalent circuit diagram of a first transmission line transformer of a unbalanced-to-balanced transformation circuit according to a modification of the sixth embodiment.

### DETAILED DESCRIPTION

### First Embodiment

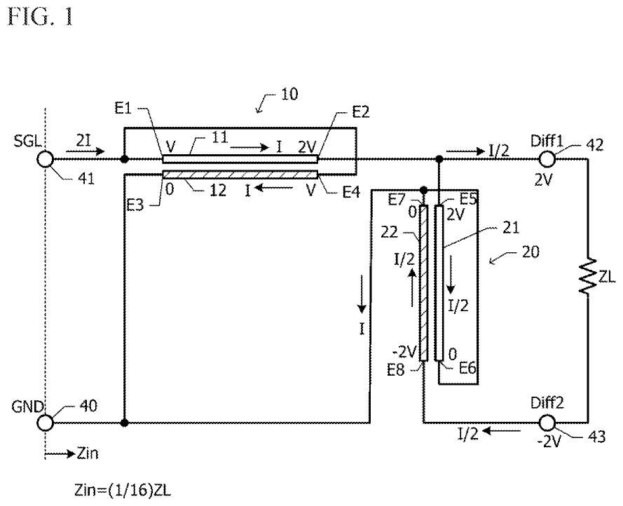

A unbalanced-to-balanced transformation circuit according to a first embodiment will be described with reference to FIGS. 1 to 4D.

FIG. 1 is an equivalent circuit diagram of the unbalanced-to-balanced transformation circuit according to the first embodiment. The unbalanced-to-balanced transformation circuit according to the first embodiment includes a first transmission line transformer 10 and a second transmission line transformer 20 that are dependently coupled to each other. The first transmission line transformer 10 and the second transmission line transformer 20 are both Ruthroff-type transmission line transformers. The first transmission line transformer 10 includes a first main line 11 and a first sub-line 12, which are a pair of transmission lines coupleable to each other by electromagnetic field coupling. The second transmission line transformer 20 includes a second main line 21 and a second sub-line 22, which are a pair of transmission lines coupleable to each other by electromagnetic field coupling (hereinafter simply referred to as “coupling”). In FIG. 1, the first main line 11 and the second main line 21 are represented by narrow, elongated rectangles that are left white, and the first sub-line 12 and the second sub-line 22 are represented by narrow, elongated rectangles that are shaded with hatching.

The unbalanced-to-balanced transformation circuit according to the first embodiment further includes an unbalanced-signal input/output node SGL for inputting and outputting unbalanced signals, a pair of balanced-signal input/output nodes Diff1 and Diff2 for inputting and outputting balanced signals, and a ground node GND to which a ground potential can be fed. For example, the unbalanced-signal input/output node SGL is implemented by an external connection terminal 41 for unbalanced signal, and the ground node GND is implemented by an external connection terminal 40 for the ground. The balanced-signal input/output nodes Diff1 and Diff2 are respectively implemented together with a first external connection terminal 42 for balanced signal and a second external connection terminal 43 for balanced signal. In this specification, a “node” for establishing connection with the outside is referred to as an “external connection terminal”. It can also be said that an “external connection terminal” is a node for establishing connection with an external circuit.

The first main line 11 and the first sub-line 12 of the first transmission line transformer 10 are coupled such that the direction from a first end E1, which is one end of the first main line 11, to a second end E2, which is the other end of the first main line 11, is the same as the direction from a third end E3, which is one end of the first sub-line 12, to a fourth end E4, which is the other end of the first sub-line 12. The fourth end E4 is coupled to the first end E1. The third end E3 is coupled to the ground node GND. The first end E1 is coupled to the unbalanced-signal input/output node SGL.

The second main line 21 and the second sub-line 22 of the second transmission line transformer 20 are coupled such that the direction from a fifth end E5, which is one end of the second main line 21, to a sixth end E6, which is the other end of the second main line 21, is identical to the direction from a seventh end E7, which is one end of the second sub-line 22, to an eighth end E8, which is the other end of the second sub-line 22. The fifth end E5 is coupled to the second end E2 of the first main line 11 of the first transmission line transformer 10. The sixth end E6 and the seventh end E7 are coupled to the ground node GND. The fifth end E5 and the eighth end E8 are respectively coupled to the balanced-signal input/output nodes Diff1 and Diff2 in a pair.

Next, a function of the first transmission line transformer 10 will be described. The line length of the first main line 11 is the same as the line length of the first sub-line 12. When a radio-frequency current flows through the first main line 11, the same amount of odd-mode radio-frequency current flows through the first sub-line 12. As illustrated in FIG. 1, when an amount I of radio-frequency current flows from the first end E1 to the second end E2 through the first main line 11, the same amount I of radio-frequency current flows from the fourth end E4 to the third end E3 through the first sub-line 12. At this time, the amount of radio-frequency current flowing from the unbalanced-signal input/output node SGL into the first transmission line transformer 10 is 2I.

The electric potential at the unbalanced-signal input/output node SGL is denoted by V. The electric potential at the first end E1 and the electric potential at the fourth end E4 are also V. Because the third end E3 is coupled to the ground node GND, the electric potential at the third end E3 is 0. Because the line length of the first main line 11 is the same as the line length of the first sub-line 12, the potential difference between the first end E1 and the second end E2 is equal to the potential difference between the third end E3 and the fourth end E4. As a result, the electric potential at the second end E2 is 2V.

In an impedance transformation circuit including the unbalanced-signal input/output node SGL as an input port and the second end E2 as an output port, the voltage at the output port is twice the voltage at the input port, and the current at the output port is ½ of the current at the input port. Thus, the first transmission line transformer 10 functions as an impedance transformation circuit for receiving an unbalanced signal as an input signal and outputting an unbalanced signal as an output signal, with an impedance transformation ratio of 4.

Next, a function of the second transmission line transformer 20 will be described. The line length of the second main line 21 is the same as the line length of the second sub-line 22. When a radio-frequency current flows through the second main line 21, the same amount of odd-mode radio-frequency current flows through the second sub-line 22. The current flowing through the second main line 21 and the current flowing through the second sub-line 22 are equal in amount but opposite in direction. As a result, the radio-frequency current flowing from the second end E2 of the first transmission line transformer 10 toward the second transmission line transformer 20 is equally divided into the fifth end E5 and the balanced-signal input/output node Diff1. When the amount of current flowing from the second end E2 of the first transmission line transformer 10 toward the second transmission line transformer 20 is I, the amount of current flowing in the balanced-signal input/output nodes Diff1 and Diff2 is (½)I.

The electric potential at the fifth end E5 of the second main line 21 is equal to the electric potential at the second end E2 of the first transmission line transformer 10, which is 2V. Because the electric potential at the sixth end E6 is 0, the potential difference between the fifth end E5 and the sixth end E6 of the second main line 21 is 2V. Because the line length of the second main line 21 is the same as the line length of the second sub-line 22, the potential difference between the fifth end E5 and the sixth end E6 is equal to the potential difference between the seventh end E7 and the eighth end E8. As a result, the potential difference between the seventh end E7 and the eighth end E8 is also 2V. The electric potential at the seventh end E7 is 0, and thus, the electric potential at the eighth end E8 is −2V.

The electric potential at the balanced-signal input/output node Diff2, which is equal to the electric potential at the eighth end E8, is −2V. The electric potential at the other balanced-signal input/output node Diff1 is equal to the electric potential at the second end E2 of the first transmission line transformer 10, which is 2V. As a result, the voltage across the pair of the balanced-signal input/output nodes Diff1 and Diff2 is 4V.

In a unbalanced-to-balanced transformation line including the second end E2 of the first transmission line transformer 10 as an input port and the balanced-signal input/output nodes Diff1 and Diff2 as output ports, the voltage at the output ports is twice the voltage at the input port, and the current at the output ports is ½ of the current at the input port. Thus, the second transmission line transformer 20 functions as a unbalanced-to-balanced transformation circuit in which the balanced impedance is four times the unbalanced impedance.

Next, an impedance transformation function of the unbalanced-to-balanced transformation circuit including the first transmission line transformer 10 and the second transmission line transformer 20 will be described. It is assumed that a load impedance ZL is coupled between the balanced-signal input/output nodes Diff1 and Diff2. The electric potential at the unbalanced-signal input/output node SGL is ¼ of the potential difference between the balanced-signal input/output nodes Diff1 and Diff2. The current flowing through the unbalanced-signal input/output node SGL is four times the current flowing through the load. As a result, the balanced impedance is sixteen times the unbalanced impedance.

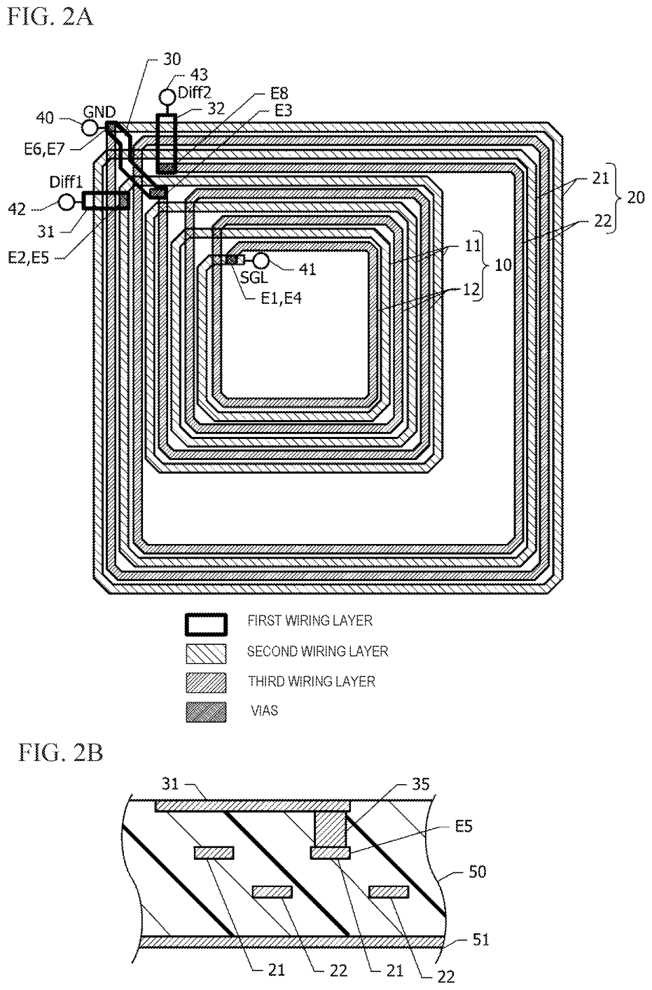

FIG. 2A is a plan view of the unbalanced-to-balanced transformation circuit according to the first embodiment. The unbalanced-to-balanced transformation circuit according to the first embodiment includes conductive patterns in multilayer wiring layers in a common substrate and vias coupling the wiring layers. Such a unbalanced-to-balanced transformation circuit can be manufactured by an integrated passive device (IPD) process. In FIG. 2A, the conductive patterns in a first wiring layer, which is the topmost wiring layer, are indicated by thick outlines. The conductive patterns in a second wiring layer, which is the second layer from the top, and the conductive patterns in a third wiring layer, which is the third layer from the top, are respectively shaded with light hatching of diagonal lines from upper left to lower right and dark hatching of diagonal lines from upper right to lower left. The locations of the vias are shaded with the darkest hatching.

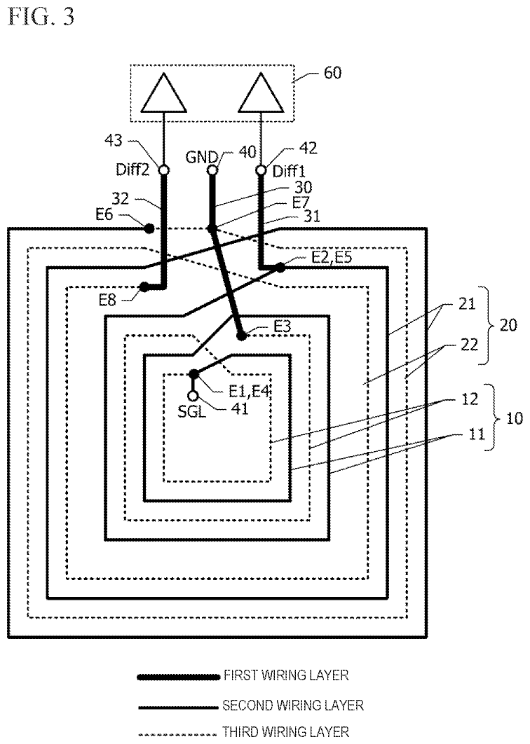

FIG. 3 schematically illustrates the shapes of the transmission lines of the unbalanced-to-balanced transformation circuit according to the first embodiment, as viewed in plan view. In FIG. 3, the conductive patterns in the first wiring layer are illustrated by bold solid lines, the conductive patterns in the second wiring layer are illustrated by thin solid lines, and the conductive patterns in the third wiring layer are illustrated by dashed lines. The locations of the vias are indicated by black circle symbols.

A ground wiring line 30, a first wiring line 31, and a second wiring line 32 are disposed in the first wiring layer. The ground wiring line 30 is coupled to the external connection terminal 40 for ground. The first wiring line 31 and the second wiring line 32 are respectively coupled to the first external connection terminal 42 for balanced signal and the second external connection terminal 43 for balanced signal.

The first main line 11 and the first sub-line 12 of the first transmission line transformer 10 and the second main line 21 and the second sub-line 22 of the second transmission line transformer 20 are formed by individual spiral conductive patterns. The first main line 11 and the second main line 21 are disposed in the second wiring layer. The first sub-line 12 and the second sub-line 22 are disposed in the third wiring layer.

When viewed in plan view, the first main line 11 and the first sub-line 12 form double spirals, and the second main line 21 and the second sub-line 22 form double spirals. The first transmission line transformer 10 including the first main line 11 and the first sub-line 12 are surrounded by the second transmission line transformer 20 including the second main line 21 and the second sub-line 22. The second main line 21 and the second sub-line 22 extend along the outlines of squares or rectangles in plan view. The first main line 11 and the first sub-line 12 also extend along the outlines of squares or rectangles in plan view.

As illustrated in FIG. 2A, the first main line 11 and the first sub-line 12 are positioned closer to one vertex (hereinafter referred to as the “vertex closest to the first transmission line transformer 10”) of the almost square or rectangle defined by the second main line 21 and the second sub-line 22 than the other vertexes.

Of the first main line 11, an inner end (the first end E1) is coupled to the external connection terminal 41 for unbalanced signal, and an outer end (the second end E2) is coupled to the first wiring line 31. Of the first sub-line 12, an inner end (the fourth end E4) is coupled to the external connection terminal 41 for unbalanced signal, an outer end (the third end E3) is coupled to the ground wiring line 30 disposed in the first wiring layer. The first end E1 of the first main line 11 and the fourth end E4 of the first sub-line 12 are coupled to each other by a via.

As illustrated in FIG. 2A, the first main line 11 extends from the first end E1, which is the inner end, to the second end E2, which is the outer end, while turning in the counterclockwise direction; the first sub-line 12 extends from the fourth end E4, which is the inner end, to the third end E3, which is the outer end, while turning in the clockwise direction. This means that the first main line 11 and the first sub-line 12 are coupled such that the direction from the first end E1 to the second end E2 of the first main line 11 is identical to the direction from the third end E3 to the fourth end E4 of the first sub-line 12. The first main line 11 and the first sub-line 12 each forms approximately three turns. As illustrated in FIG. 3, the first main line 11 may extend from the first end E1, which is the inner end, to the second end E2, which is the outer end, while turning in the clockwise direction; the first sub-line 12 may extend from the fourth end E4, which is the inner end, to the third end E3, which is the outer end, while turning in the counterclockwise direction.

Of the second main line 21, an inner end (the fifth end E5) is coupled to the first wiring line 31, an outer end (the sixth end E6) is coupled to the ground wiring line 30. The fifth end E5 of the second main line 21 is also coupled to the second end E2 of the first main line 11. The first main line 11 and the second main line 21 are formed by a line of conductive patterns in the same wiring layer.

Of the second sub-line 22, an inner end (the eighth end E8) is coupled to the second wiring line 32, and an outer end (the seventh end E7) is coupled to the ground wiring line 30. The sixth end E6 of the second main line 21 and the seventh end E7 of the second sub-line 22 are coupled to each other by a via.

As illustrated in FIG. 2A, the second main line 21 extends from the fifth end E5, which is the inner end, to the sixth end E6, which is the outer end, turning in the counterclockwise direction; the second sub-line 22 extends from the eighth end E8, which is the inner end, to the seventh end E7, which is the outer end, while turning in the clockwise direction. This means that the second main line 21 and the second sub-line 22 are coupled such that the direction from the fifth end E5 to the sixth end E6 of the second main line 21 is identical to the direction from the seventh end E7 to the eighth end E8 of the second sub-line 22. The second main line 21 and the second sub-line 22 each forms approximately two turns. As illustrated in FIG. 3, the second main line 21 may extend from the fifth end E5, which is the inner end, to the sixth end E6, which is the outer end, while turning in the clockwise direction; the second sub-line 22 extends from the eighth end E8, which is the inter end, to the seventh end E7, which is the outer end, while turning in the counterclockwise direction.

The eight ends, namely the first end E1 through the eighth end E8, are positioned near the vertex closest to the first transmission line transformer 10 (the upper-left vertex in FIG. 2A). When viewed in plan view, the external connection terminal 40 for ground, the first external connection terminal 42, and the second external connection terminal 43 are positioned outside the region defined by the second transmission line transformer 20. The external connection terminal 40 for ground, the first external connection terminal 42, and the second external connection terminal 43 are arranged parallel to the second main line 21 and the second sub-line 22 that are shaped as spirals. The external connection terminal 41 for unbalanced signal is disposed in the region defined by the first transmission line transformer 10.

The first external connection terminal 42 is coupled to the second end E2 and the fifth end E5 by the first wiring line 31. The first wiring line 31 extends from the fifth end E5 of the second main line 21 to a location outside the region defined by the second transmission line transformer 20, in the direction perpendicular to the second main line 21. The second external connection terminal 43 is coupled to the eighth end E8 by the second wiring line 32. The second wiring line 32 extends from the eighth end E8 of the second sub-line 22 to a location outside the region defined by the second transmission line transformer 20, in the direction perpendicular to the second sub-line 22.

As illustrated in FIG. 3, the first external connection terminal 42 and the second external connection terminal 43 are respectively coupled to a pair of input ports of a differential amplifier 60. When an unbalanced signal is inputted to the unbalanced-signal input/output node SGL, the unbalanced signal can be transformed into a balanced signal through the first transmission line transformer 10 and the second transmission line transformer 20 and inputted to the differential amplifier 60. In this process, impedance transformation is performed.

FIG. 2B is a sectional view of a portion of the unbalanced-to-balanced transformation circuit according to the first embodiment. A multilayer wiring structure is formed in a substrate 50. The first wiring line 31 is disposed in the first wiring layer, which is the topmost layer. The second main line 21 is disposed in the second wiring layer, which is the second layer from the top. The second sub-line 22 is disposed in the third wiring layer, which is the third layer from the top. A ground conductor 51 is disposed at the substrate 50. The fifth end E5 of the second main line 21 is coupled to the first wiring line 31 by a via 35. In an example, the width of the second main line 21 and the second sub-line 22 is greater than or equal to 5 μm and smaller than or equal to 10 μm, and the thickness of the second main line 21 and the second sub-line 22 is approximately 3 μm.

For example, a magnetic insulator or dielectric can be used for the substrate 50. Examples of a substrate made of a dielectric include a resin substrate and a ceramic substrate. An insulator layer formed on a semiconductor substrate may be used as the substrate 50.

Next, effects of the first embodiment will be described. In the first embodiment, as described with reference to FIG. 1, the balanced impedance is sixteen times the unbalanced impedance. The balanced impedance can be made greater than or equal to the unbalanced impedance.

As illustrated in FIGS. 2A and 3, when viewed in plan view, the first transmission line transformer 10 is surrounded by the second transmission line transformer 20. This configuration reduces the size of the region occupied by the first transmission line transformer 10 and the second transmission line transformer 20, as compared to when the first transmission line transformer 10 and the second transmission line transformer 20 are arranged side by side in a plane of the substrate 50. This configuration thus reduces the size of the unbalanced-to-balanced transformation circuit.

As illustrated in FIG. 2A, the first main line 11 and the second main line 21 are formed by a line of conductive patterns in the same wiring layer. This configuration reduces the number of vias.

As illustrated in FIG. 2A, the first wiring line 31 extends from the second end E2 and the fifth end E5 to a location outside the region defined by the second transmission line transformer 20 in the direction perpendicular to the second main line 21 (the direction perpendicular to a direction parallel to the spiral shapes). This configuration shortens the wiring length from the second end E2 and the fifth end E5 to the first external connection terminal 42 of the first wiring line 31. Similarly, this configuration shortens the wiring length from the eighth end E8 to the second external connection terminal 43 of the second wiring line 32.

Further, the second end E2, the fifth end E5, and the eighth end E8 are positioned near the vertex closest to the first transmission line transformer 10. This configuration shortens the wiring length of the first wiring line 31 and the wiring length of the second wiring line 32, as compared to when the geometrical center of the first transmission line transformer 10 coincides with the geometrical center of the second transmission line transformer 20. The expression “the second end E2 is positioned near the vertex closest to the first transmission line transformer 10” means that among the distances from the four vertexes of the square or rectangle along the outermost transmission line out of the second main line 21 and the second sub-line 22 of the second transmission line transformer 20 to the second end E2, the distance from the vertex closest to the first transmission line transformer 10 to the second end E2 is shortest.

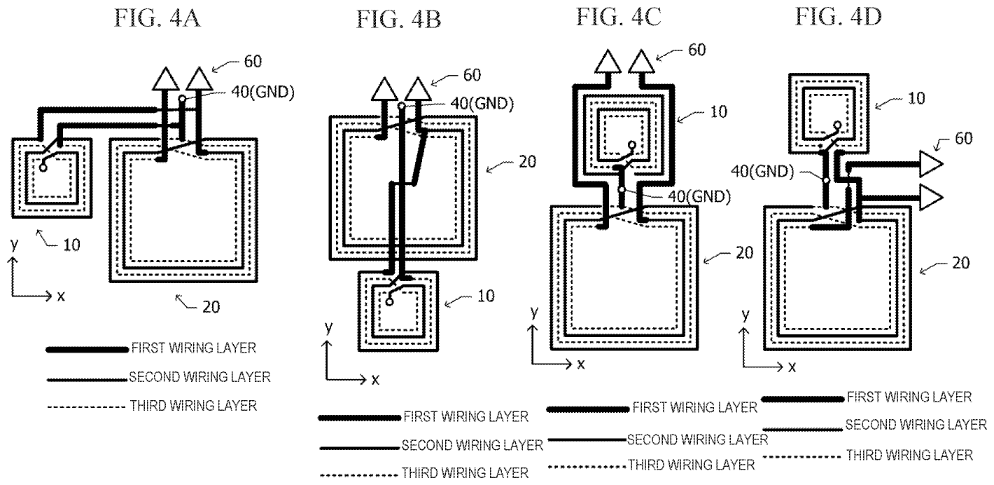

Next, effects of the first embodiment will be described in comparison to comparative examples in FIGS. 4A to 4D. FIGS. 4A to 4D schematically illustrate positional relationships between the first transmission line transformer 10 and the second transmission line transformer 20 of the unbalanced-to-balanced transformation circuit, according to comparative examples, as viewed in plan view. In all the comparative examples, the first transmission line transformer 10 is positioned outside the second transmission line transformer 20. To facilitate understanding of the positional relationships among the first transmission line transformer 10, the second transmission line transformer 20, and other constituent elements, an xy orthogonal coordinate system is provided. In FIGS. 4A to 4D, similarly to FIG. 3, the conductive patterns in the first wiring layer are illustrated by bold solid lines, the conductive patterns in the second wiring layer are illustrated by thin solid lines, and the conductive patterns in the third wiring layer are illustrated by dashed lines.

In the comparative example illustrated in FIG. 4A, the first transmission line transformer 10 and the second transmission line transformer 20 are arranged parallel to the x direction. The differential amplifier 60 and the external connection terminal 40 for ground are positioned on the positive side along the y axis with respect to the second transmission line transformer 20. The ends of the transmission line of the first transmission line transformer 10 and the ends of the transmission line of the second transmission line transformer 20 are positioned on the positive side along the y axis.

In this arrangement, the wiring length from the second transmission line transformer 20 to the differential amplifier 60 and the external connection terminal 40 for ground is relatively short. However, the wiring length from the first transmission line transformer 10 to the differential amplifier 60 and the external connection terminal 40 for ground is relatively long.

In the comparative example illustrated in FIG. 4B, the differential amplifier 60 and the external connection terminal 40 for ground, the second transmission line transformer 20, and the first transmission line transformer 10 are arranged parallel to the y direction in the order presented. In this configuration, the wiring line from the first transmission line transformer 10 to the differential amplifier 60 and the wiring line from the first transmission line transformer 10 to the external connection terminal 40 for ground extend across the second transmission line transformer 20. This configuration thus increases the wiring lengths of the wiring lines.

In the comparative example illustrated in FIG. 4C, the differential amplifier 60, the first transmission line transformer 10, the external connection terminal 40 for ground, and the second transmission line transformer 20 are arranged parallel to the y direction in the order presented. In this configuration, the wiring lines coupling the second transmission line transformer 20 and the differential amplifier 60 extend across or around the first transmission line transformer 10. This configuration thus increases the wiring lengths of the wiring lines.

In the comparative example illustrated in FIG. 4D, the first transmission line transformer 10, the external connection terminal 40 for ground, and the second transmission line transformer 20 are arranged parallel to the y direction in the order presented. The differential amplifier 60 is positioned on the positive side along the x axis with respect to the external connection terminal 40 for ground. In this configuration, the wiring length from the first transmission line transformer 10 to the differential amplifier 60 and the wiring length from the second transmission line transformer 20 to the differential amplifier 60 are relatively long.

In all the comparative examples illustrated in FIGS. 4A to 4D, the wiring lengths of the wiring lines leading to the differential amplifier 60 are relatively long. In the first embodiment, as illustrated in FIG. 3, the first transmission line transformer 10 is disposed in the region defined by the second transmission line transformer 20. This configuration prevents the wiring lines leading to the differential amplifier 60 from becoming long.

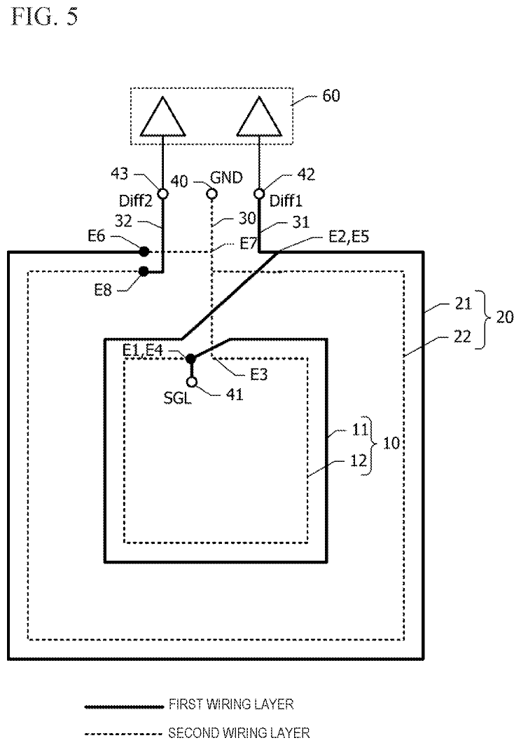

Next, a unbalanced-to-balanced transformation circuit according to a modification of the first embodiment will be described with reference to FIG. 5. FIG. 5 schematically illustrates the shapes of the transmission lines of the unbalanced-to-balanced transformation circuit according to the modification of the first embodiment, as viewed in plan view. In FIG. 5, the conductive patterns in the first wiring layer are illustrated by solid lines, and the conductive patterns in the second wiring layer are illustrated by dashed lines.

In the modification of the first embodiment illustrated in FIG. 5, the first main line 11, the first sub-line 12, the second main line 21, and the second sub-line 22 each forms approximately one turn. In this modification, the first wiring line 31 coupling the second end E2 and the fifth end E5 and the first external connection terminal 42 is disposed in the same first wiring layer as the first main line 11 and the second main line 21. The ground wiring line 30 coupling the third end E3, the sixth end E6, the seventh end E7, and the external connection terminal 40 for ground to each other is disposed in the same second wiring layer as the first sub-line 12 and the second sub-line 22. The second wiring line 32 coupling the eighth end E8 and the second external connection terminal 43 is disposed in the same first wiring layer as the second main line 21.

As described above, as in the modification of the first embodiment illustrated in FIG. 5, when the first main line 11, the first sub-line 12, the second main line 21, and the second sub-line 22 each forms approximately one turn, the unbalanced-to-balanced transformation circuit can be realized by two wiring layers.

The optimum line lengths of the first main line 11, the first sub-line 12, the second main line 21, and the second sub-line 22 are determined by the design frequency. Once the line lengths of these transmission lines are determined, the number of turns of each transmission line can be determined based on the line length. As the number of turns increases, the size of the region occupied by the first transmission line transformer 10 and the second transmission line transformer 20 decreases. Thus, increasing the number of turns is beneficial for reducing the size of the unbalanced-to-balanced transformation circuit. By contrast, decreasing the number of turns of transmission line to one is beneficial for reducing the number of wiring layers.

Next, a unbalanced-to-balanced transformation circuit according to another modification of the first embodiment will be described. In the first embodiment (FIG. 2A), the first transmission line transformer 10 is surrounded by the second transmission line transformer 20 in plan view. Conversely, the second transmission line transformer 20 may be surrounded by the first transmission line transformer 10.

In the first embodiment (FIG. 2A), the balanced-signal input/output nodes Diff1 and Duff2 are respectively implemented together with the first external connection terminal 42 and the second external connection terminal 43. However, passive elements, which are disposed in the substrate 50 (FIG. 2B), may be coupled between the balanced-signal input/output node Diff1 and the first external connection terminal 42 and between the balanced-signal input/output node Diff2 and the second external connection terminal 43. When an insulating film disposed on a semiconductor substrate is used as the substrate 50, active elements, which are disposed in the semiconductor substrate, may be couped between the balanced-signal input/output node Diff1 and the first external connection terminal 42 and between the balanced-signal input/output node Diff2 and the second external connection terminal 43. Similarly, a passive element or active element, which is disposed in the substrate 50, may be coupled between the external connection terminal 41 for unbalanced signal and the unbalanced-signal input/output node SGL.

### Second Embodiment

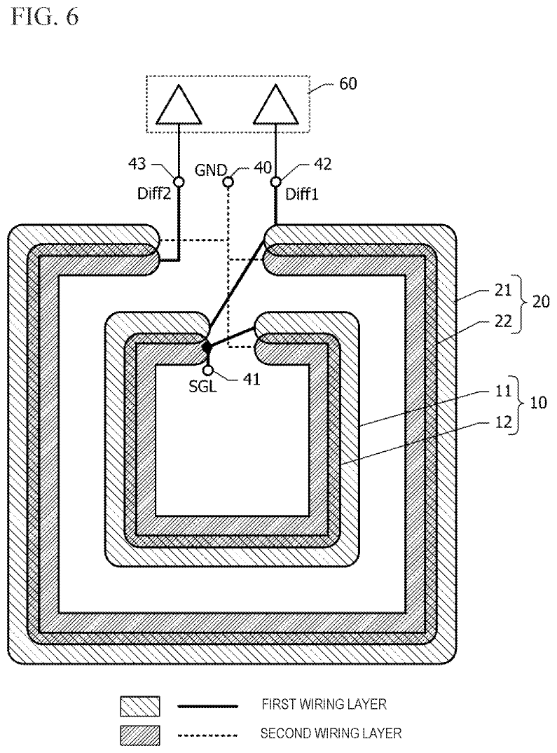

Next, a unbalanced-to-balanced transformation circuit according to a second embodiment will be described with reference to FIG. 6. In the following, descriptions of the configurational features common to the unbalanced-to-balanced transformation circuit according to the first embodiment, as described with reference to FIGS. 1 to 4D, will not be repeated.

FIG. 6 schematically illustrates a positional relationship among transmission lines in a unbalanced-to-balanced transformation circuit according to the second embodiment, as viewed in plan view. In FIG. 6, some particular conductive patterns in the first wiring layer are shaded with light hatching of diagonal lines from upper left to lower right, and some particular conductive patterns in the second wiring layer are shaded with dark hatching of diagonal lines from upper right to lower left. The other conductive patterns in the first wiring layer are illustrated by solid lines, and the other conductive patterns in the second wiring layer are illustrated by dashed lines. In the first embodiment (FIG. 2A), the first main line 11 and the first sub-line 12 do not overlap except at the intersections, and the second main line 21 and the second sub-line 22 also do not overlap except at the intersections.

By contrast, in the second embodiment, a portion of the width of the first main line 11 coincides with a portion of the width of the first sub-line 12 in plan view. Similarly, a portion of the width of the second main line 21 coincides with a portion of the width of the second sub-line 22. The first main line 11, the first sub-line 12, the second main line 21, and the second sub-line 22 each forms approximately one turn. Positioning two coupled transmission lines in an overlapping manner increases the parallel capacitance per unit length of the coupled transmission lines. As a result, the characteristic impedance of the coupled transmission lines decreases.

Next, effects of the second embodiment will be described. Also in the second embodiment, similarly to the first embodiment, the balanced impedance can be made greater than or equal to the unbalanced impedance. Further, in the second embodiment, the characteristic impedance of the coupled transmission lines is relatively low. This configuration enables impedance transformation and unbalanced-to-balanced transformation in a lower impedance region.

Next, a modification of the second embodiment will be described. In the second embodiment, a portion of the width of the first main line 11 coincides with a portion of the width of the first sub-line 12 in plan view. However, the entire width of the first main line 11 may coincide with the entire width of the first sub-line 12 may overlap. Similarly, the entire width of the second main line 21 may coincide with the entire width of the second sub-line 22. Alternatively, when viewed in plan view, one of the first main line 11 and the first sub-line 12 may be positioned within the other. Similarly, when viewed in plan view, one of the second main line 21 and the second sub-line 22 may be positioned within the other.

In the second embodiment, the first main line 11, the first sub-line 12, the second main line 21, and the second sub-line 22 each forms approximately one turn. However, these transmission lines may each form more than one turns.

### Third Embodiment

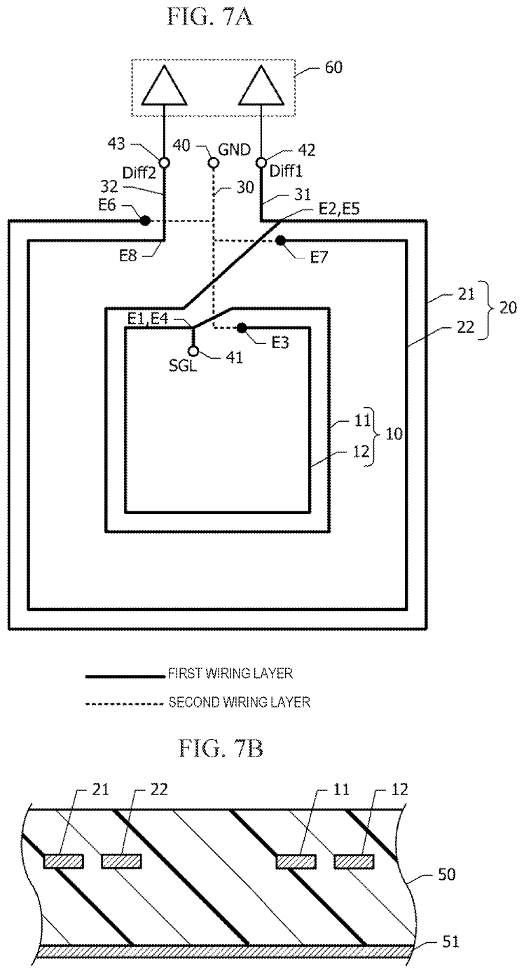

Next, a unbalanced-to-balanced transformation circuit according to a third embodiment will be described with reference to FIGS. 7A and 7B. In the following, descriptions of the configurational features common to the unbalanced-to-balanced transformation circuit according to the first embodiment, as described with reference to FIGS. 1 to 4D, will not be repeated.

FIG. 7A schematically illustrates a positional relationship among transmission lines in a unbalanced-to-balanced transformation circuit according to the third embodiment, as viewed in plan view. In FIG. 7A, the conductive patterns in the first wiring layer are illustrated by solid lines, and the conductive patterns in the second wiring layer are illustrated by dashed lines. In the first embodiment (FIG. 3), the first main line 11 and the first sub-line 12 are disposed in different wiring layers, and the second main line 21 and the second sub-line 22 are disposed in different wiring layers. By contrast, in the third embodiment, the first main line 11, the first sub-line 12, the second main line 21, and the second sub-line 22 are disposed in the same first wiring layer.

The first wiring line 31 coupling the second end E2 of the first main line 11 and the fifth end E5 of the second main line 21 to the first external connection terminal 42 is disposed in the same first wiring layer as the first main line 11 and the second main line 21. The second wiring line 32 coupling the eighth end E8 of the second sub-line 22 to the second external connection terminal 43 is disposed in the same first wiring layer as the second sub-line 22. The ground wiring line 30 coupling the third end E3 of the first sub-line 12, the seventh end E7 of the second sub-line 22, and the sixth end E6 of the second main line 21 to the external connection terminal 40 for ground is disposed in the second wiring layer different from the first wiring layer.

FIG. 7B is a sectional view of a portion of the unbalanced-to-balanced transformation circuit according to the third embodiment. The first main line 11, the first sub-line 12, the second main line 21, and the second sub-line 22 are disposed in the same first wiring layer in the substrate 50. A side of the first main line 11 and a side of the first sub-line 12 face each other. The first main line 11 and a side of the first sub-line 12 are coupled by edge-coupling. Similarly, the second main line 21 and the second sub-line 22 are coupled by edge-coupling.

Next, effects of the third embodiment will be described. Also in the third embodiment, similarly to the first embodiment, the balanced impedance can be made greater than or equal to the unbalanced impedance.

Further, in the third embodiment, the first main line 11 and the first sub-line 12 are arranged parallel to an in-plane direction, the second main line 21 and the second sub-line 22 are arranged parallel to the in-plane direction. In this manner, regardless of the thickness of the interlayer insulating film that provides insulation between the wiring layers, the first main line 11 and the first sub-line 12, as well as the second main line 21 and the second sub-line 22, can be positioned close to each other. Positioning the first main line 11 and the first sub-line 12 close to each other and the second main line 21 and the second sub-line 22 close to each other increases the parallel capacitance per unit length of the coupled transmission lines. As a result, the characteristic impedance of the coupled transmission lines decreases. This configuration enables impedance transformation and unbalanced-to-balanced transformation in a lower impedance region.

### Fourth Embodiment

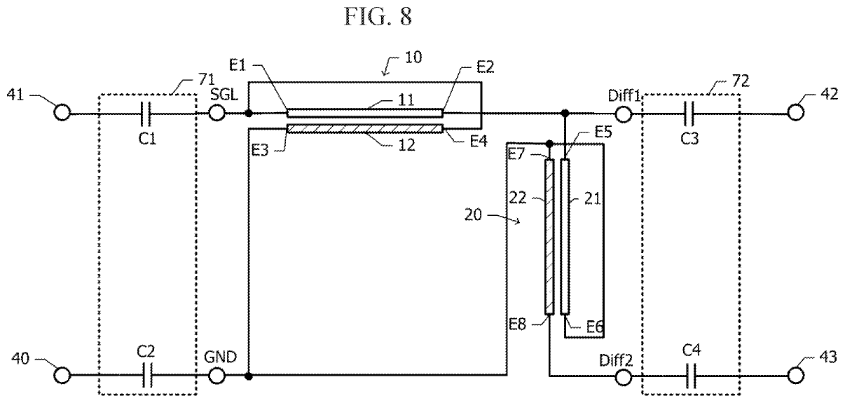

Next, a unbalanced-to-balanced transformation circuit according to a fourth embodiment will be described with reference to FIG. 8. In the following, descriptions of the configurational features common to the unbalanced-to-balanced transformation circuit according to the first embodiment, as described with reference to FIGS. 1 to 4D, will not be repeated.

FIG. 8 is an equivalent circuit diagram of the unbalanced-to-balanced transformation circuit according to the fourth embodiment. In the first embodiment (FIG. 1), the ground node GND, the unbalanced-signal input/output node SGL, the balanced-signal input/output nodes Diff1 and Diff2 are directly coupled respectively to the external connection terminal 40 for ground, the external connection terminal 41 for unbalanced signal, the first external connection terminal 42 for balanced signal, and the second external connection terminal 43. By contrast, in the fourth embodiment, a first impedance matching circuit 71 is coupled between the ground node GND and the unbalanced-signal input/output node SGL, and the external connection terminal 40 for ground and the external connection terminal 41 for unbalanced signal. Additionally, a second impedance matching circuit 72 is coupled between the balanced-signal input/output nodes Diff1 and Diff2, and the first external connection terminal 42 and the second external connection terminal 43.

For example, the first impedance matching circuit 71 includes a capacitor C1, which is coupled between the unbalanced-signal input/output node SGL and the external connection terminal 41, and a capacitor C2, which is coupled between the ground node GND and the external connection terminal 40 for ground. The second impedance matching circuit 72 includes a capacitor C3, which is coupled between the balanced-signal input/output node Diff1 and the first external connection terminal 42, and a capacitor C4, which is coupled between the balanced-signal input/output node Diff2 and the second external connection terminal 43. Next, effects of the fourth embodiment will be described. Also in the fourth embodiment, similarly to the first embodiment, the balanced impedance can be made greater than or equal to the unbalanced impedance.

Further, in the fourth embodiment, coupling the first impedance matching circuit 71 and the second impedance matching circuit 72 expands the impedance control range. By coupling the capacitors C1, C2, C3, and C4, direct current isolation is provided between the first transmission line transformer 10 and the second transmission line transformer 20, and external circuits.

Next, a modification of the fourth embodiment will be described. In the fourth embodiment, each of the first impedance matching circuit 71 and the second impedance matching circuit 72 includes a capacitor, but each of the first impedance matching circuit 71 and the second impedance matching circuit 72 may additionally include a passive element such as an inductor or resistance element. Depending on the target impedance matching condition, the appropriate circuit configuration and circuit constant of the first impedance matching circuit 71 and the second impedance matching circuit 72 can be selected. Further, either the first impedance matching circuit 71 or the second impedance matching circuit 72 may be removed.

### Fifth Embodiment

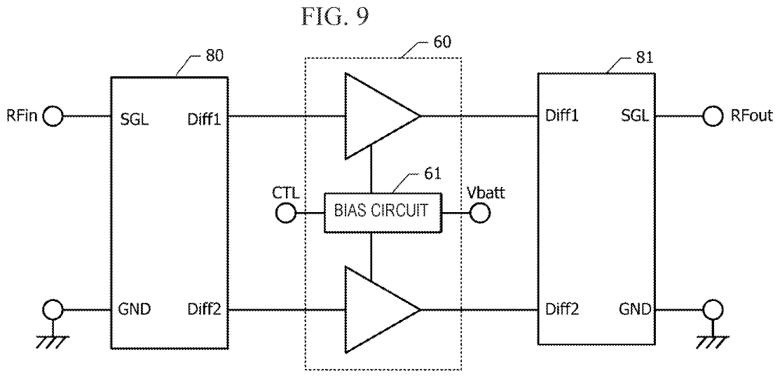

Next, a radio-frequency amplifier according to a fifth embodiment will be described with reference to FIG. 9. FIG. 9 is an equivalent circuit diagram of the radio-frequency amplifier according to the fifth embodiment.

The radio-frequency amplifier according to the fifth embodiment includes the differential amplifier 60, a first unbalanced-to-balanced transformation circuit 80, and a second unbalanced-to-balanced transformation circuit 81. As the first unbalanced-to-balanced transformation circuit 80 and the second unbalanced-to-balanced transformation circuit 81, the unbalanced-to-balanced transformation circuit according to any of the first to fourth embodiments is used.

The following describes a configuration of the differential amplifier 60. A battery power source Vbatt can be supplied to a bias circuit 61. The bias circuit 61 is operable to supply biases to a pair of amplifier circuits that constitutes the differential amplifier 60, based on a bias control signal CTL.

The pair of balanced-signal input/output nodes Diff1 and Diff2 of the first unbalanced-to-balanced transformation circuit 80 are respectively coupled to a pair of input nodes of the differential amplifier 60. A pair of output nodes of the differential amplifier 60 are respectively coupled to the balanced-signal input/output nodes Diff1 and Diff2 of the second unbalanced-to-balanced transformation circuit 81. The ground node GND of the first unbalanced-to-balanced transformation circuit 80 and the ground node GND of the second unbalanced-to-balanced transformation circuit 81 are grounded.

An unbalanced radio-frequency signal RFin can be inputted to the unbalanced-signal input/output node SGL of the first unbalanced-to-balanced transformation circuit 80. The unbalanced radio-frequency signal RFin inputted to the first unbalanced-to-balanced transformation circuit 80 is transformed into balanced signals (differential signals) by the first unbalanced-to-balanced transformation circuit 80 and inputted to the differential amplifier 60. The balanced signals outputted from the differential amplifier 60 are inputted to the second unbalanced-to-balanced transformation circuit 81. The balanced signals inputted to the second unbalanced-to-balanced transformation circuit 81 are outputted as an unbalanced radio-frequency output signal RFout from the unbalanced-signal input/output node SGL.

The first unbalanced-to-balanced transformation circuit 80 is operable to transform an unbalanced signal into a balanced signal. The first unbalanced-to-balanced transformation circuit 80 is also operable to perform impedance transformation to match the input impedance of the first unbalanced-to-balanced transformation circuit 80 with the input impedance of the differential amplifier 60. The second unbalanced-to-balanced transformation circuit 81 is operable to transform a balanced signal into an unbalanced signal. The second unbalanced-to-balanced transformation circuit 81 is also operable to perform impedance transformation to match the output impedance of the differential amplifier 60 with the load impedance of the second unbalanced-to-balanced transformation circuit 81.

Next, effects of the fifth embodiment will be described. Typically, the output impedance and input impedance of the differential amplifier 60 are greater than or equal to 100Ω and smaller than or equal to 200Ω. The characteristic impedance of the transmission lines for transferring the unbalanced radio-frequency signal RFin and the unbalanced radio-frequency output signal RFout is 50Ω. Thus, impedance matching is achieved by making the balanced impedance of the first unbalanced-to-balanced transformation circuit 80 and the balanced impedance of the second unbalanced-to-balanced transformation circuit 81 greater than the unbalanced impedance of the first unbalanced-to-balanced transformation circuit 80 and the unbalanced impedance of the second unbalanced-to-balanced transformation circuit 81.

Using the unbalanced-to-balanced transformation circuit according to any of the first to fourth embodiments as the first unbalanced-to-balanced transformation circuit 80 and the second unbalanced-to-balanced transformation circuit 81 ensures that the balanced impedance is greater than or equal to the unbalanced impedance. This configuration thus achieves impedance matching between the input side and output side of the differential amplifier 60. Depending on the circuit configuration of the input side and output side of the differential amplifier 60, either the first unbalanced-to-balanced transformation circuit 80 or the second unbalanced-to-balanced transformation circuit 81 may be removed.

### Sixth Embodiment

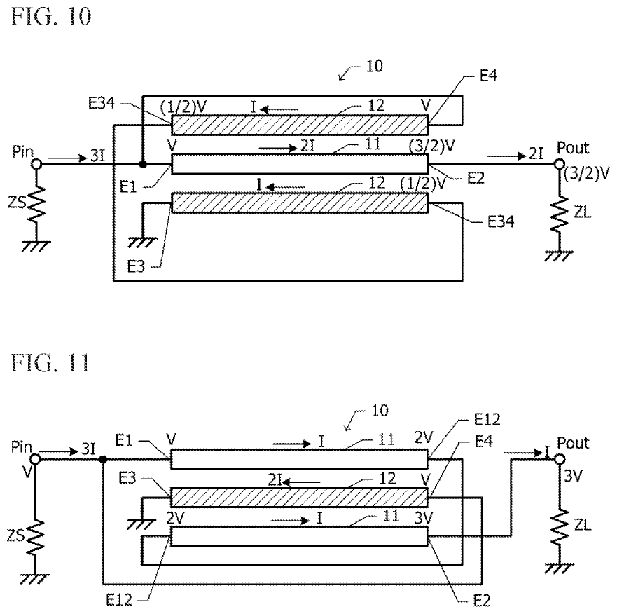

Next, a unbalanced-to-balanced transformation circuit according to a sixth embodiment will be described with reference to FIG. 10. In the following, descriptions of the configurational features common to the unbalanced-to-balanced transformation circuit according to the first embodiment, as described with reference to FIGS. 1 to 4D, will not be repeated.

FIG. 10 is an equivalent circuit diagram of the first transmission line transformer 10 of the unbalanced-to-balanced transformation circuit according to the sixth embodiment. In FIG. 10, the first main line 11 is represented by a narrow, elongated rectangle that is left white, and the first sub-line 12 is represented by narrow, elongated rectangles that are shaded with hatching. In the first embodiment (FIG. 1), the line length of the first main line 11 is equal to the line length of the first sub-line 12. By contrast, in the sixth embodiment, the line length of the first sub-line 12 is twice the line length of the first main line 11. The first main line 11 is coupleable to the portion from the third end E3 of the first sub-line 12 to a midpoint E34 and the portion from the midpoint E34 to the fourth end E4. An input port Pin is coupled to the first end E1 of the first main line 11 and the fourth end E4 of the first sub-line 12. The second end E2 of the first main line 11 is coupled to an output port Pout.

The amount of odd mode current flowing through the first sub-line 12 is ½ of the amount of current flowing through the first main line 11. When the amount of current flowing through the first sub-line 12 is I, the amount of current flowing through the first main line 11 is 2I. The amount of current flowing from the input port Pin into the first transmission line transformer 10 is 3I. The amount of current flowing out from the output port Pout is 2I.

When the electric potential at the input port Pin is denoted by V, the electric potential at the midpoint E34 of the first sub-line 12 is (½)V, and the electric potential at the second end E2 of the first main line 11 is (3/2)V. As a result, the electric potential at the output port Pout is (3/2)V. When the level of impedance coupled to the input port Pin is denoted by ZS, and the level of impedance coupled to the output port Pout is ZL, the impedance ZL is 2.25 times greater than ZS. As described above, the impedance transformation ratio of the first transmission line transformer 10 in the unbalanced-to-balanced transformation circuit according to the sixth embodiment is 2.25.

Next, a unbalanced-to-balanced transformation circuit according to a modification of the sixth embodiment will be described with reference to FIG. 11. FIG. 11 is an equivalent circuit diagram of the first transmission line transformer 10 of the unbalanced-to-balanced transformation circuit according to the modification of the sixth embodiment. In the modification of the sixth embodiment illustrated in FIG. 11, the line length of the first main line 11 is twice the line length of the first sub-line 12. The portion from the first end E1 of the first main line 11 to a midpoint E12 and the portion from the midpoint E12 to the second end E2 are coupleable to the first sub-line 12. When the amount I of current flows through the first main line 11, the amount 2I of odd mode current flows through the first sub-line 12.

At this time, the amount of current flowing from the input port Pin into the first transmission line transformer 10 is 3I, and the amount of current flowing out from the output port Pout is I. When the electric potential at the input port Pin is denoted by V, the electric potential at the midpoint E12 of the first main line 11 is 2V, and the electric potential at the second end E2 is 3V. As a result, the electric potential at the output port Pout is also 3V. The impedance ZL is nine times greater than ZS. As described above, the impedance transformation ratio of the first transmission line transformer 10 in the unbalanced-to-balanced transformation circuit according to the modification of the sixth embodiment illustrated in FIG. 11 is 9.

Next, effects of the sixth embodiment and its modification will be described. As in the sixth embodiment and its modification, by changing the line length of the first main line 11 and the line length of the first sub-line 12 of the first transmission line transformer 10, the impedance transformation ratio of the first transmission line transformer 10 can be changed. Accordingly, the impedance transformation ratio of the unbalanced-to-balanced transformation circuit including the first transmission line transformer 10 and the second transmission line transformer 20 that are dependently coupled can be changed.

The aforementioned embodiments are illustrative, and partial replacement or combination of the configuration elements presented in the different embodiments is possible. The same effects and advantages of the same configurational feature among multiple embodiments are not described in every embodiment. The present disclosure is not limited to the aforementioned embodiments. For example, various modifications, improvements, and combinations would be readily apparent to those skilled in the art.

Based on the embodiments described in this specification, the following disclosure is disclosed.

<1>

A unbalanced-to-balanced transformation circuit comprising:
a first transmission line transformer configured to perform impedance transformation, the first transmission line transformer being configured to receive an unbalanced signal as an input signal and output an unbalanced signal as an output signal;
a second transmission line transformer configured to perform unbalanced-to-balanced transformation;
an unbalanced-signal input/output node; and
a pair of balanced-signal input/output nodes, wherein the first transmission line transformer includes a first main line and a first sub-line;
the first main line and the first sub-line are coupled such that a direction from a first end that is one end of the first main line to a second end that is another end of the first main line is identical to a direction from a third end that is one end of the first sub-line to a fourth end that is another end of the first sub-line;
the fourth end is coupled to the first end;
the third end is grounded; and
the first end is coupled to the unbalanced-signal input/output node, and the second transmission line transformer includes a second main line and a second sub-line;
the second main line and the second sub-line are coupled such that a direction from a fifth end that is one end of the second main line to a sixth end that is another end of the second main line is identical to a direction from a seventh end that is one end of the second sub-line to an eighth end that is another end of the second sub-line;
the fifth end is coupled to the second end;
the sixth end and the seventh end are grounded; and
the fifth end and the eighth end are respectively coupled to the pair of balanced-signal input/output nodes.

<2>

The unbalanced-to-balanced transformation circuit according to <1>, wherein
the first main line, the first sub-line, the second main line, and the second sub-line are formed by spiral conductive patterns disposed in a common substrate, and
when viewed in plan view, one of the first transmission line transformer including the first main line and the first sub-line and the second transmission line transformer including the second main line and the second sub-line is surrounded by another of the first transmission line transformer and the second transmission line transformer.

<3>

The unbalanced-to-balanced transformation circuit according to <2>, wherein
the first main line, the first sub-line, the second main line, and the second sub-line are formed by conductive patterns in a plurality of wiring layers provided in the substrate,
the first main line and the first sub-line are disposed in different wiring layers among the plurality of wiring layers, and the second main line and the second sub-line are disposed in different wiring layers among the plurality of wiring layers.

<4>

The unbalanced-to-balanced transformation circuit according to <2> or <3>, wherein
the first main line and the second main line are formed by a line of conductive patterns in the same wiring layer.

<5>

The unbalanced-to-balanced transformation circuit according to <3> or <4>, wherein
at least a portion of the first main line coincides with at least a portion of the first sub-line in plan view, and
at least a portion of the second main line coincides with at least a portion of the second sub-line in plan view.

<6>

The unbalanced-to-balanced transformation circuit according to <5>, wherein
at least a portion of a width of the first main line coincides with at least a portion of a width of the first sub-line in plan view, and
at least a portion of a width of the second main line coincides with at least a portion of a width of the second sub-line in plan view.

<7>

The unbalanced-to-balanced transformation circuit according to <2>, wherein
the first main line, the first sub-line, the second main line, and the second sub-line are formed by conductive patterns in a plurality of wiring layers provided in the substrate,
the first main line and the first sub-line are disposed in the same wiring layer among the plurality of wiring layers, and the second main line and the second sub-line are disposed in the same wiring layer among the plurality of wiring layers.

<8>

The unbalanced-to-balanced transformation circuit according to any one of <2> to <7>, further comprising:
a first external connection terminal for balanced signal and a second external connection terminal for balanced signal that are provided at the substrate;
a first wiring line coupling the first external connection terminal to the fifth end; and
a second wiring line coupling the second external connection terminal to the eighth end, wherein
the first transmission line transformer is surrounded by the second transmission line transformer in plan view,
when viewed in plan view, the first external connection terminal and the second external connection terminal are arranged parallel to the second main line and the second sub-line that are shaped as spirals, outside a region defined by the second transmission line transformer,
the first wiring line extends from the fifth end to a location outside the region defined by the second transmission line transformer, in a direction perpendicular to the second main line, and
the second wiring line extends from the eighth end to a location outside the region defined by the second transmission line transformer, in a direction perpendicular to the second sub-line.

<9>

The unbalanced-to-balanced transformation circuit according to any one of <1> to <8>, further comprising a first impedance matching circuit coupled between the first end and the unbalanced-signal input/output node and between the third end and ground.

<10>

The unbalanced-to-balanced transformation circuit according to any one of <1> to <9>, further comprising a second impedance matching circuit coupled between the second end and the eighth end, and the pair of balanced-signal input/output nodes.

<11>

A radio-frequency amplifier comprising:
a differential amplifier including a pair of input nodes and a pair of output nodes; and
one or two unbalanced-to-balanced transformation circuits, each of the one or two unbalanced-to-balanced transformation circuits being the unbalanced-to-balanced transformation circuit according to any one of <1> to <9>, wherein
the unbalanced-to-balanced transformation circuits include a first unbalanced-to-balanced transformation circuit, and
the pair of balanced-signal input/output nodes of the first unbalanced-to-balanced transformation circuit is coupled to one pair of the pair of input nodes and the pair of output nodes of the differential amplifier.

<12>

The radio-frequency amplifier according to <11>, wherein
the unbalanced-to-balanced transformation circuits include a second unbalanced-to-balanced transformation circuit as well as the first unbalanced-to-balanced transformation circuit, and
the pair of balanced-signal input/output nodes of the second unbalanced-to-balanced transformation circuit is coupled to another pair of the pair of input nodes and the pair of output nodes of the differential amplifier, the other pair being not coupled to the first unbalanced-to-balanced transformation circuit.

What is claimed is:

1. A unbalanced-to-balanced transformation circuit comprising:
a first transmission line transformer configured to perform impedance transformation, to receive an unbalanced signal as an input signal, and to output an unbalanced signal as an output signal;
a second transmission line transformer configured to perform unbalanced-to-balanced transformation;
an unbalanced-signal input/output node; and
a pair of balanced-signal input/output nodes,
wherein the first transmission line transformer comprises a first main line and a first sub-line;
wherein the first main line and the first sub-line are coupled such that a direction from a first end of the first main line to a second end of the first main line is identical to a direction from a first end of the first sub-line to a second end of the first sub-line,
wherein the second end of the first sub-line is coupled to the first end of the first main line,
wherein the first end of the first sub-line is grounded,
wherein the first end of the first main line is coupled to the unbalanced-signal input/output node,
wherein the second transmission line transformer comprises a second main line and a second sub-line,
wherein the second main line and the second sub-line are coupled such that a direction from a first end of the second main line to a second end of the second main line is identical to a direction from a first end of the second sub-line to a second end of the second sub-line,
wherein the first end of the second main line is coupled to the second end of the first main line,
wherein the second end of the second main line and the first end of the second sub-line are grounded, and
wherein the first end of the second main line and the second end of the second sub-line are respectively coupled to the pair of balanced-signal input/output nodes.

2. The unbalanced-to-balanced transformation circuit according to claim 1,
wherein the first main line, the first sub-line, the second main line, and the second sub-line are spiral conductive patterns in a common substrate, and
wherein one of the first transmission line transformer and the second transmission line transformer is surrounded by another of the first transmission line transformer and the second transmission line transformer in a plan view of the unbalanced-to-balanced transformation circuit.

3. The unbalanced-to-balanced transformation circuit according to claim 2,
wherein the first main line, the first sub-line, the second main line, and the second sub-line are spiral conductive patterns in a plurality of wiring layers in the substrate, and
wherein the first main line and the first sub-line are in different wiring layers among the plurality of wiring layers, and the second main line and the second sub-line are in different wiring layers among the plurality of wiring layers.

4. The unbalanced-to-balanced transformation circuit according to claim 2, wherein the first main line and the second main line are spiral conductive patterns in the same wiring layer.

5. The unbalanced-to-balanced transformation circuit according to claim 3,
wherein at least a portion of the first main line coincides with at least a portion of the first sub-line in the plan view, and
wherein at least a portion of the second main line coincides with at least a portion of the second sub-line in the plan view.

6. The unbalanced-to-balanced transformation circuit according to claim 5,
wherein at least a portion of a width of the first main line coincides with at least a portion of a width of the first sub-line in the plan view, and
wherein at least a portion of a width of the second main line coincides with at least a portion of a width of the second sub-line in the plan view.

7. The unbalanced-to-balanced transformation circuit according to claim 2,
wherein the first main line, the first sub-line, the second main line, and the second sub-line are spiral conductive patterns in a plurality of wiring layers provided in the substrate,
the first main line and the first sub-line are in the same wiring layer among the plurality of wiring layers, and the second main line and the second sub-line are in the same wiring layer among the plurality of wiring layers.

8. The unbalanced-to-balanced transformation circuit according to claim 2, further comprising:
a first external connection terminal for a first balanced signal and a second external connection terminal for a second balanced signal that are at the substrate;
a first wiring line coupling the first external connection terminal to the first end of the second main line; and
a second wiring line coupling the second external connection terminal to the second end of the second sub-line,
wherein the first transmission line transformer is surrounded by the second transmission line transformer in the plan view,
wherein the first external connection terminal and the second external connection terminal are arranged parallel to the second main line and the second sub-line, outside a region defined by the second transmission line transformer, in the plain view,
wherein the first wiring line extends in a direction perpendicular to the second main line from the first end of the second main line to a location outside the region defined by the second transmission line transformer, and
wherein the second wiring line extends in a direction perpendicular to the second sub-line from the second end of the second sub-line to a location outside the region defined by the second transmission line transformer.

9. The unbalanced-to-balanced transformation circuit according to claim 1, further comprising a first impedance matching circuit coupled between the first end of the first main line and the unbalanced-signal input/output node, and between the first end of the first sub-line and ground.

10. The unbalanced-to-balanced transformation circuit according to claim 1, further comprising a second impedance matching circuit coupled between the second end of the first main line and the second end of the second sub-line, and the pair of balanced-signal input/output nodes.

11. A radio-frequency amplifier comprising:
a differential amplifier comprising a pair of input nodes and a pair of output nodes; and
a first unbalanced-to-balanced transformation circuit according to claim 1,
wherein the pair of balanced-signal input/output nodes of the first unbalanced-to-balanced transformation circuit is coupled to one pair of the pair of input nodes and the pair of output nodes of the differential amplifier.

12. The radio-frequency amplifier according to claim 11, further comprising:
a second unbalanced-to-balanced transformation circuit,
wherein the pair of balanced-signal input/output nodes of the second unbalanced-to-balanced transformation circuit is coupled to another pair of the pair of input nodes and the pair of output nodes of the differential amplifier, the other pair not being coupled to the first unbalanced-to-balanced transformation circuit.
